(19) United States
(12) Patent Application Publication
(10) Pub. No.: US 2009/0294937 A1
(43) Pub. Date: Dec. 3, 2009

(54) TWO-WAY HEAT EXTRACTION FROM PACKAGED SEMICONDUCTOR CHIPS

(75) Inventor: Darvin Renne Edwards, Garland, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/541,280

(22) Filed: Aug. 14, 2009

Related U.S. Application Data
(63) Continuation of application No. 11/535,749, filed on Sep. 27, 2006.

(51) Int. Cl. H01L 23/34

(52) U.S. Cl. 257/675; 257/E23.08

(57) ABSTRACT

One embodiment of the invention is a semiconductor device (500) with a first (500a) and a second (500b) surface, a package including a plastic molding compound (501), and a semiconductor chip (502) inside the package. A first metal sheet (510, 401) covers at least portions of the first package surface (500a), has a thickness (510a, 401a), and is preferably made of copper to operate as a heat spreader. At least one metal connector (511, 402) is in contact with the sheet, has the same thickness as the sheet, and is shaped to be operable as a mechanical spring between sheet and chip. An opening (512, 404) in the sheet is located adjacent to the connector and filled with molding compound. A second metal sheet (520) covers at least portions of the second package surface (500b) and is connected to the chip.

This is a continuation of application Ser. No. 11/535,749 filed Sep. 27, 2006, the contents of which are herein incorporated by reference in its entirety.

### FIELD OF THE INVENTION

The present invention is related in general to the field of semiconductor devices and processes and more specifically to thermally enhanced configurations of semiconductor packages offering two-way heat extraction, and to a method of fabricating these configurations using transfer molding technology.

### DESCRIPTION OF THE RELATED ART

Removing the thermal heat generated by active components belongs to the most fundamental challenges in integrated circuit technology. Coupled with the ever shrinking component feature sizes and increasing density of device integration is an ever increasing device speed, density of power and thermal energy generation. In order to keep the active components at their optimum (low) operating temperatures and speed, this heat must continuously be dissipated and removed to outside heat sinks. This effort, unfortunately, becomes increasingly harder, the higher the energy density becomes.

In known technology, the most effective approach to heat removal focuses on thermal transport through the thickness of the semiconductor chip from the active surface to the passive surface. The passive surface, in turn, is attached to the chip mount pad of a metallic leadframe so that the thermal energy can flow into the chip mount pad of the metallic leadframe. When properly formed, this leadframe can act as a heat spreader to an outside heat sink.

From a standpoint of thermal efficiency, however, this approach has shortcomings. The heat generated by active components must traverse the thickness of the semiconductor chip in order to exit from the chip. The heat then faces the thermal barrier of the attach material (typically a polymer) before it can enter the leadframe.

### SUMMARY OF THE INVENTION

Applicant realized that for leadframe-based devices a technical solution is missing to remove the heat generated by active components directly from the IC into a metallic heat conductor and a heat spreader positioned in proximity to the active components experiencing the highest temperature rise in device operation.

Applicant further investigated approaches, which are equally applicable to leadframe-based packages and Ball Grid Array packages, where power dissipation and thermal characteristics are lagging, especially when multi-layer copper-laminated resin substrates have to be used for electrical performance. The package structure should be based on fundamental physics and design concepts flexible enough to be applied for different semiconductor product families and a wide spectrum of design and assembly variations. The structure should not only meet high thermal and electrical performance requirements, but should also achieve improvements towards the goals of enhanced process yields and device reliability.

One embodiment of the invention is a semiconductor device with a first and a second surface, a package including a plastic molding compound, and a semiconductor chip inside the package. A first metal sheet covers at least portions of the first package surface, has a thickness, and is preferably made of copper to operate as a heat spreader. At least one metal connector is in contact with the sheet, has the same thickness as the sheet, and is shaped to be operable as a mechanical spring between sheet and chip. An opening in the sheet is located adjacent to the connector and filled with molding compound. A second metal sheet covers at least portions of the second package surface and is connected to the chip.

Another embodiment of the invention is a method for fabricating a semiconductor device with a two-way heat extraction from the chip. A semiconductor chip is (thermally conductively) attached to the pad of a leadframe. A mold is provided with a cavity including a bottom, sidewalls, and a lid. The leadframe with the attached chip is placed on the bottom of the cavity. A metal sheet is provided, which has a portion pressed out to form at least one connector shaped as a spring with a length, while leaving an adjacent opening. The sheet is placed over the chip so that the connector rests on the chip surface and the spring length elevates the sheet above the cavity sidewalls. Placing the lid flat on the sheet, it compresses the spring until the lid rests on the sidewalls. The cavity is then filled with molding compound, whereby the attached chip, the compressed spring, and portions of the segments are embedded, while the sheet opening is filled. When the compound is polymerized, the position of the compressed spring is frozen and the sheet is incorporated into the surface of the finished device, ready to operate as a thermal spreader for the heat conducted by the connector from the chip. Additional cooling is provided by the pad of the leadframe.

The technical advances represented by the invention, as well as the objects thereof, will become apparent from the following description of the preferred embodiments of the invention, when considered in conjunction with the accompanying drawings and the novel features set forth in the appended claims.

### BRIEF DESCRIPTION OF THE DRAWINGS

FIG. 1 illustrates a schematic cross section of a semiconductor device with a heat spreader connected to the chip as an embodiment of the invention.

FIG. 2 is a schematic perspective view of an embodiment of the invention including a metal sheet, a connector, and an opening in the sheet operable as a heat spreader.

FIG. 3A is a plot displaying thermal modeling data; the junction-to-case thermal resistance is shown as a function of the geometrical connection to a heat spreader.

FIG. 3B is a schematic cross section of a semiconductor device with a heat spreader shaped according to the invention, the geometrical connection between spreader and chip defining the parameter plotted in FIG. 3A.

FIG. 4 is a schematic perspective view of another embodiment of the invention including a metal sheet, two connectors, and an opening in the sheet operable as a heat spreader.

FIG. 5 illustrates a schematic cross section of an SON semiconductor device with leadframe and wire bonds including a heat spreader shaped and connected to the chip according to the invention.

FIG. 6 depicts a schematic cross section of an surface mount semiconductor device with leadframe and wire bonds including a heat spreader shaped and connected to the chip according to the invention.

FIG. 7 illustrates a schematic cross section of an SON semiconductor device with laminated substrate and flip-chip including a heat spreader shaped and connected to the chip according to the invention.

FIG. 8A is a schematic cross section of a flip-chip SON semiconductor device with a heat spreader shaped and connected to the chip according to the invention; the FIG. highlights the geometry and material of the connection.

FIG. 8B shows a schematic cross section of a detail of FIG. 8A.

FIG. 8C is a plot displaying thermal modeling data; the junction-to-case thermal resistance is shown as a function of the geometrical connection to the heat spreader for several attachment materials between chip and connector.

### DETAILED DESCRIPTION OF THE PREFERRED EMBODIMENTS

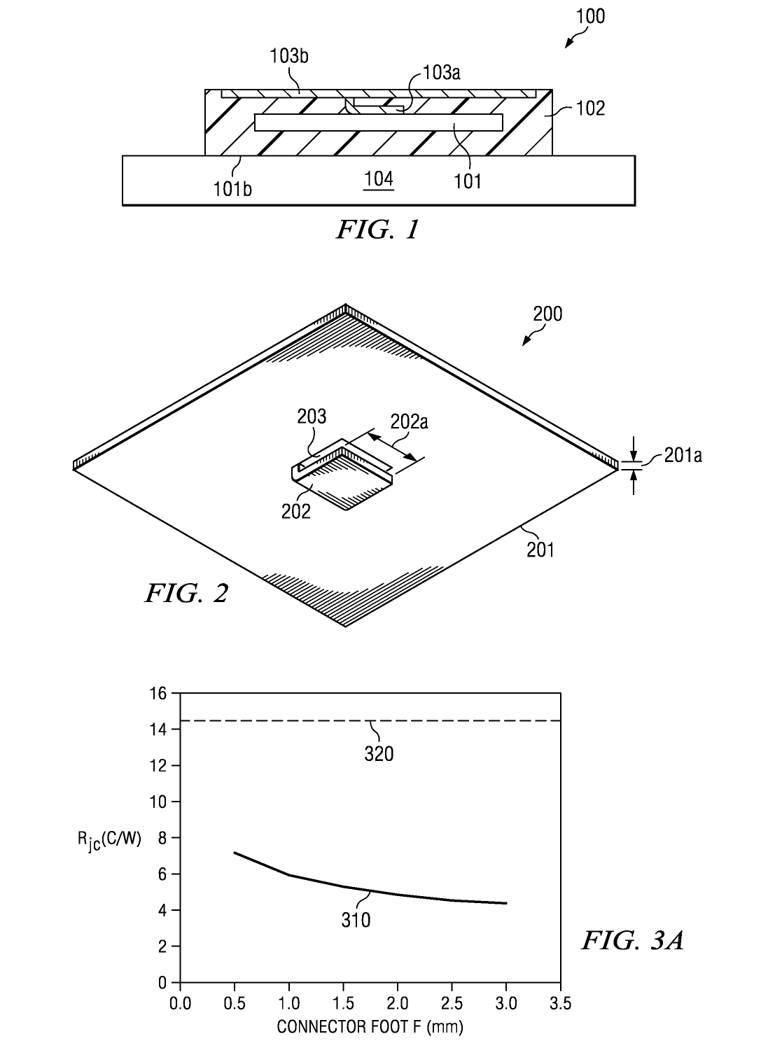

FIG. 1 illustrates schematically an embodiment of the invention, generally designated 100, for improving both the thermal conductance and the temperature gradient to enhance the thermal flux vertically away from the heat-generating active components of semiconductor chip 101. Embedded in encapsulating plastic material 102 of only low-to-moderate thermal conductivity, the thermal energy generated by operating the active components of chip 101 would increase the temperature in the neighborhood of the components rapidly, if the energy would not be transported away by the connector 103a, attached to chip 101, to the heat spreader 103b.

In FOURIER's approach to solving the differential equation of thermal conductance, the thermal flux Q per unit of time is equal to the product of thermal conductivity λ multiplied by the gradient of temperature T, in the direction of decreasing temperature, and by the area q perpendicular to the temperature gradient:

dQ/dt=−λ·(gradT)·q,

where Q is the vector (in magnitude and direction) of thermal flux, and λ is the thermal conductivity, a materials characteristic. The thermal flux is in the direction of the temperature difference and is proportional to the magnitude of that difference.

When, over the length l, the temperature drop is steady and uniform from the high temperature T2 to the low temperature T1, then (grad T) reduces to (T2−T1)/l:

dQ/dt=−λ·(q/l)·(T2−T1).

λ·(q/l) is called the thermal conductance, and the inverse value l/(λ·q) is called thermal resistance (in analogy to OHM's law).

In the present invention, the improvement of λ·q is provided by the high thermal conductivity (copper) and the geometry of conductor 103a; the improvement of (grad T) is provided by the relatively low temperature of heat spreader 103b. Both contributions result in enhanced the thermal flux vertically away from the heat-generating active components on the active surface of the semiconductor chip.

In addition to this enhanced thermal flux vertically away from the active chip surface, there is the possibility of conducting thermal energy in the opposite direction through the semiconductor material of the chip to its second (passive) surface 101b and beyond into substrate 104 (metallic leadframe or laminate).

FIG. 2 illustrates in more detail the construction of a preferred embodiment of the heat spreader, generally designated 200, and the connector. The heat spreader includes a metal sheet 201; FIG. 2 is a perspective view of the spreader from the underside. The sheet is preferably copper or copper alloy, in the range of thickness 201a from about 100 to 250 μm. Alternatively, the sheet may be made of aluminum or aluminum alloy, although aluminum's thermal conductivity is about 40% lower than copper. The area of spreader 201 is selected so that it is smaller than, but approaching the area of the intended semiconductor package (see FIG. 1).

By pressing (such as stamping or punching), at least one metal conductor 202 is formed from the metal sheet of spreader 201. Conductor 202 has thus substantially the same thickness 201a as spreader 201. Further, as shown in FIG. 1 and FIG. 2, the shape of the conductor 103a (202 in FIG. 2) is selected to enable it to operate as a mechanical spring between sheet 103b and chip 101 (see FIG. 1). Connector 202 has a length 202a. FIG. 2 points out that, due to the mechanical process of fabrication, an opening 203 in sheet 201 is left adjacent to connector 202.

As shown in FIG. 4, more than one connector (for example, two connectors) may be pressed from the original sheet, serving as thermal conductors as well as mechanical springs, and leaving openings in the sheet.

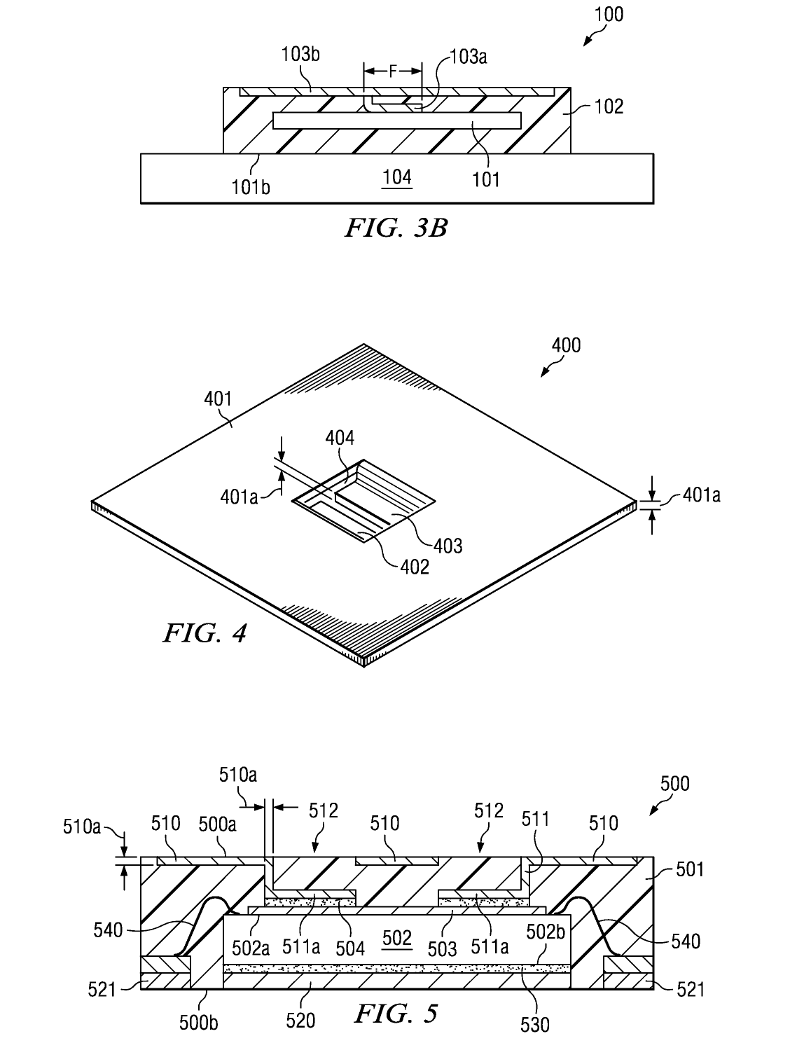

Thermal modeling data in FIG. 3A highlight the impact of the heat spreader and its connector on improving the thermal device characteristics. Plotted in FIG. 3A is R_{jc} (junction-to-case thermal resistance, also called Θ_{jc} theta-jc, measured in ° C./W) as a function of the connector foot F of the heat spreader (measured in mm); FIG. 3B defines the extension of the connector foot. Curve 310 shows the low values of R_{jc} obtained by removing heat through the connector and the spreader, while curve 320 shows the about twice higher values without the benefit of connector and spreader.

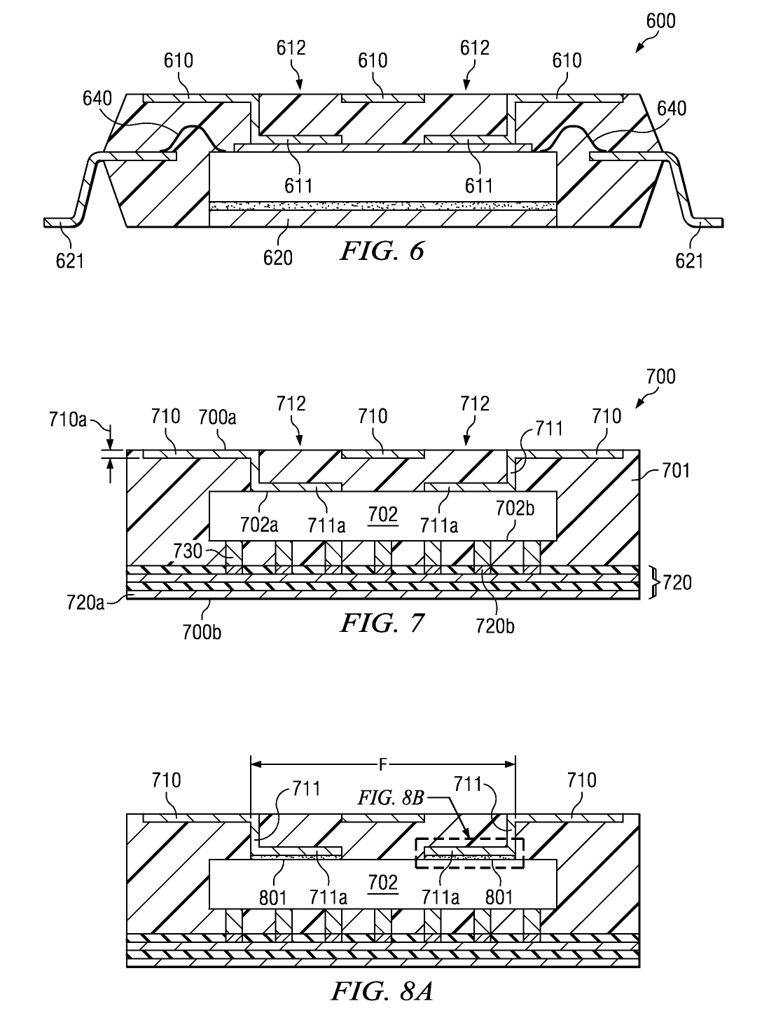

FIG. 4 depicts another embodiment of the invention, a heat spreader with connectors, generally designated 400. The heat spreader includes a metal sheet 401, perspectively viewed from the top side in FIG. 4. The sheet is preferably made of copper or copper alloy; the thickness 401a ranges preferably from about 100 to 250 μm. Alternatively, the sheet may be made of aluminum or aluminum alloy. The area of spreader 201 is selected so that it is smaller than, but approaching the area of the intended semiconductor package (see FIGS. 5 and 6). The spreader has two connectors 402 and 403, which have been formed from sheet 401 by a mechanical technique such as stamping or punching. The connectors thus have substantially the same thickness 401a as sheet 401. The fabrication step also leaves an opening 404 in the metal sheet adjacent to the connectors 402 and 403.

The connectors 402 and 403 are shaped to be operable as mechanical springs between sheet 401 and the semiconductor chip surface, which the connectors will contact and onto which they may be attached (see later method description). In addition to the two connectors shown in FIG. 4, there may be one or more connectors formed from sheet 401. They will further improve the heat flow from the chip to the spreader and thus the cooling of the hot spots of the chip under operation. The spreader in turn may be connected to an outside heat sink at low temperature in order to maintain a steep temperature gradient.

FIGS. 5, 6 and 7 illustrate semiconductor device embodiments of the invention. FIG. 5 shows a wire bonded device using a leadframe, a representative of the so-called SON (small outline no-lead) devices. FIG. 6 is another wire bonded device using a leadframe for a surface-mount small-outline package. FIG. 7 depicts a bump-connected flip-chip device using a laminated substrate.

The packaged device of FIG. 5, generally designated 500, has a first surface 500a and a second surface 500b, and a plastic molding compound 501 for encapsulation. Each device surface includes metallic and plastic portions. Inside the package is a semiconductor chip 502 with first surface 502a and second surface 502b. First surface 502a has active semiconductor components; several of these components reach high temperatures during device operation and require cooling in order to maintain undiminished device speed and full operating power.

At least a portion of device surface 500a includes a first metal sheet 510, which serves as a heat spreader. It is preferably made of copper; the thickness 510a ranges preferably from about 100 to 250 μm. The spreader has one or more connectors 511, which have preferably been formed from the sheet and thus have substantially the same thickness 510a. The connectors 511 establish the path of low thermal resistance between the spreader and the first chip surface 502a. The connectors have a shape to be operable as mechanical springs between sheet 510 and chip 502 (functionality see fabrication method below); connector 511 includes a connector foot 511a for resting the connector on chip surface 502a.

As illustrated in FIG. 5, a technique to facilitate cooling for many devices includes a layer 503 of copper over certain active components or circuit portions. Layer 503 is separated from the components by a protective insulating surface layer (not shown in FIG. 5). Layer 503 may be produced within a wide range of thicknesses, for example between 0.5 to 25 μm. For devices having layer 503, the connector foot 511a rests on layer 503 rather than directly on chip surface 502a and may be attached to layer 503. A preferred method of attaching is by a layer 504 of solder; alternatively, the attachment may be achieved by a layer 504 of thermally conductive adhesive.

As FIG. 5 shows, device 500 includes on its surface 500a openings 512 in metal sheet 510, which are located adjacent to connector 511 and are filled with molding compound. First metal sheet 510 and the compound-filled openings 512 together form the planar device surface 500a.

In FIG. 5, the second chip surface 502b is attached to a second metal sheet 520, which, for the device depicted, is the chip pad of a leadframe. The attachment is achieved by a thermally conductive adhesive layer 530, preferably a silver-filled epoxy or polyimide. Alternatively, second sheet 520 may be the outer metal layer of a laminated substrate. As FIG. 5 shows, device 500 uses bonding wires 540 to connect to segments 521 of the leadframe employed by SON devices.

In FIG. 6, the embodiment 600 also uses bonding wires 640; they connect, however, to leadframe segments 621 formed for surface mount devices. The first metal sheet 610, operating as a heat spreader, the spring-like connectors 611, the compound-filled openings 612, and the second metal sheet 620 are analogous to device 500 shown in FIG. 5.

Another embodiment of the invention is a method for fabricating a semiconductor device as illustrated in FIGS. 5 and 6. The method starts by providing a semiconductor chip with a first surface including active components, and a second surface. Next, a leadframe is provided, which includes a chip attach pad and lead segments. The second chip surface is attached to the leadframe pad, preferably using a thermally conductive adhesive. After the attachment, bonding wires are used to connect the chip electrically to segments of the leadframe.

Next, a mold is provided, which has a cavity including a bottom, sidewalls, and a lid; the lid can be opened and closed. When the lid is opened, the leadframe with the attached chip is placed on the bottom of the cavity; the leadframe thus lays flat on the cavity bottom.

In the next process step, a metal sheet is provided, which has been prepared so that a portion of the sheet has been pressed out (for instance, by punching or stamping) to form at least one connector. The connector is shaped to operate as a mechanical spring; it also has a foot of a certain length. Due to the forming process, an opening has been left in the sheet adjacent to the connector. The sheet is placed over the first chip surface so that the connector foot rests on the first chip surface and the spring-shaped portion of the connector elevates the sheet above the cavity sidewalls.

Then, in order to close the lid, it is placed flat on the sheet; by pressing the lid against the sheet, the spring is compressed until the lid rests on the sidewalls.

The cavity is then filled with molding compound, preferably by the transfer molding technique. The preferred molding compound includes an epoxy-based polymer with inorganic fillers. In the molding process, the attached chip, the compressed spring, and portions of the segments are embedded in molding compound, and the sheet opening adjacent to the connector is filled.

Finally, the compound is polymerized (for example, by storing the device at temperatures around 175° C. for several hours). This curing process freezes the position of the compressed spring and incorporates the metal sheet into the surface of the finished device.

Another embodiment of the invention is illustrated in FIG. 7. The packaged device of FIG. 7, generally designated 700, has a first surface 700a and a second surface 700b, and a plastic molding compound 701 for encapsulation. Device surface 700a includes metallic and plastic portions. Inside the package is a semiconductor chip 702 with first surface 702a and second surface 702b. Second surface 702b has active semiconductor components.

At least a portion of device surface 700a includes a first metal sheet 710, which serves as a heat spreader. It is preferably made of copper; the thickness 710a ranges from about 100 to 250 μm. The spreader has one or more connectors 711, which have preferably been formed from the sheet and thus have substantially the same thickness 710a. The connectors 711 establish the path of low thermal resistance between the spreader and the first chip surface 702a. The connectors have a shape to be operable as mechanical springs between sheet 710 and chip 702; connector 711 also includes a connector foot 711a for resting the connector on first chip surface 702a. In order to maximize the thermal heat transfer from the chip the connector (see below), foot 711a may be attached to chip surface 702a.

As FIG. 7 shows, device 700 includes on its surface 700b openings 712 in metal sheet 710, which are located adjacent to connector 711 and are filled with molding compound. First metal sheet 710 and the compound-filled openings 712 together form the planar device surface 700a.

In FIG. 7, second surface 700b of device 700 includes laminate substrate 720. In other devices, the substrate forms at least a portion of the second device surface. In FIG. 7, substrate 720 has a metal layer 720a at the outside surface, serving as a heat spreader to contribute to the cooling of device 700; further, substrate 720 has contact pads facing chip 702. Contact pads on the second chip surface 702b are connected to contact pads 720b by metal bumps 730. Preferably, the metal bumps are reflow bodies (solder balls); alternatively, they may include gold bumps. The connection itself is achieved by a flip-chip attachment process.

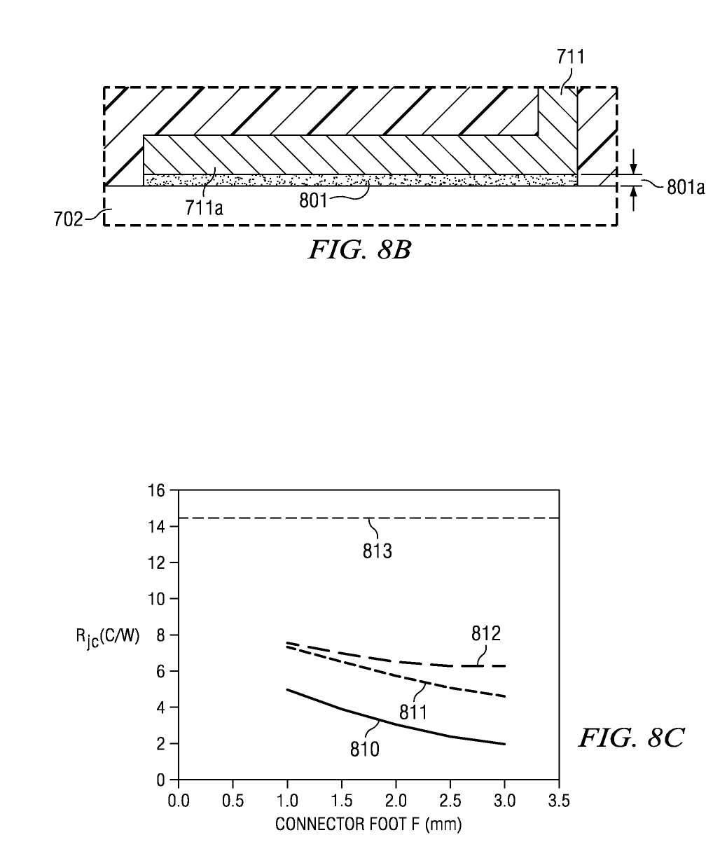

While for some devices a simple placement of connector foot 711a onto first chip surface 702a offers sufficient thermal conduction, an improvement of the thermal flux is needed for other devices. The improvement method and the results of thermal modeling are illustrated in FIGS. 8A, 8B, and 8C. For a device as represented by the embodiment of FIG. 7, the connector foot F is defined in FIG. 8A as the sum of portions 711a for all connectors 711; this length F is used for the thermal modeling.

In FIG. 8B, a portion of a connector 711 is magnified to emphasize the mode of attachment to chip 702, represented by layer 801. The thickness of layer 801 is designated 801a. For the purpose of thermal modeling, thickness 801a was assumed to be 5 μm. The results of modeling are summarized in FIG. 8C. The junction-to-case thermal resistance R_{jc} (in ° C./W) is plotted as a function of connector foot F (in mm) for three cases: Curve 810 represents perfect contact (5 μm solder layer) for connector 711a to chip 702; curve 811 represents 5 μm resin for layer 801 (resin thermal conductivity λ=0.1 W/(m·K); curve 812 represents 5 μm air gap for layer 801 (air thermal conductivity λ=0.026 W/(m·K); and for comparison, curve 813 represents the thermal resistance without the benefit of the spreader 710. The benefit of an implement using solder attachment of the conductors of the thermal spreader is obvious.

Another embodiment of the invention is a method for fabricating a semiconductor device as illustrated in FIG. 7. The method starts by providing a semiconductor chip with a first surface, and a second surface including active components and contact pads. Next, a laminated substrate is provided, which has a first and a second surface, contact pads on the first surface and a metal sheet on the second surface. The contact pads of the second chip surface are then connected to the contact pads of the first substrate surface using metal bumps, preferably solder balls or gold bumps. When solder balls are used, the step of connecting includes the reflowing of the solder balls.

Next, a mold is provided, which has a cavity including a bottom, sidewalls, and a lid; the lid can be opened and closed. When the lid is opened, the substrate with the attached chip is placed on the bottom of the cavity; the substrate thus lays flat on the cavity bottom.

In the next process step, a metal sheet is provided, which has been prepared so that a portion of the sheet has been pressed out (for instance, by punching or stamping) to form at least one connector. The connector is shaped to operate as a mechanical spring; it also has a foot of a certain length. Due to the forming process, an opening has been left in the sheet adjacent to the connector. The sheet is placed over the first chip surface so that the connector foot rests on the first chip surface and the spring-shaped portion of the connector elevates the sheet above the cavity sidewalls.

In order to maximize the thermal flux from the chip to the heat spreader, it is preferred to solder the connector foot to the first chip surface. Alternatively, a thermally conductive adhesive may be employed to attach the connector foot to the chip.

Then, in order to close the lid, it is placed flat on the sheet; by pressing the lid against the sheet, the spring is compressed until the lid rests on the sidewalls.

The cavity is then filled with molding compound, preferably by the transfer molding technique. The preferred molding compound includes an epoxy-based polymer with inorganic fillers. In the molding process, the attached chip (including the connecting metal bumps), the compressed spring, and the first substrate surface are embedded in molding compound, and the sheet opening adjacent to the connector is filled with compound.

Finally, the compound is polymerized (for example, by storing the device at temperatures around 175° C. for about 6 hours). This curing process freezes the position of the compressed spring and incorporates the metal sheet into the surface of the finished device.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

I claim:

1. A semiconductor device, comprising:
a heat spreader including a sheet of metal having an opening and an extension member extending from an edge of the opening; the extension member having a surface area substantially same as the opening, offset from the opening and parallel to the sheet; and
a semiconductor chip having a surface attached to the extension member.

2. The semiconductor of claim 1, in which the extension member is attached to the semiconductor chip with solder.

3. The semiconductor of claim 2, in which solder is attached to a portion of the semiconductor chip having a copper layer.

4. The semiconductor of claim 1, in which the opening is filled with a molding compound.

5. The semiconductor of claim 1, in which the semiconductor chip has a second surface attached to a die pad of a leadframe.

6. The semiconductor of claim 5, in which the semiconductor device is a SON device.

7. The semiconductor of claim 1, in which the semiconductor chip has a second surface attached to a die pad on a laminated substrate.

8. The semiconductor of claim 5, in which the semiconductor chip is connected to the leadframe with wire-bonds.

9. The semiconductor of claim 7, in which the semiconductor chip is connected to the substrate in a flip-chip fashion.

10. The semiconductor of claim 1, in which the extension member extends from opposite edges of the opening.
